(19) United States
(12) Patent Application Publication
(10) Pub. No.: US 2013/0020122 A1
(43) Pub. Date: Jan. 24, 2013

(54) CABLE BUNDLING STRUCTURE IN SLIDABLE ENGAGEMENT WITH CABLE

(71) Applicant: ADVANCED FLEXIBLE CIRCUITS CO., LTD., TAOYUAN COUNTY (TW)

(72) Inventors: KUO-FU SU, TAOYUAN COUNTY (TW); GWUN-JIN LIN, TAOYUAN COUNTY (TW); CHIH-HENG CHUO, TAOYUAN COUNTY (TW)

(73) Assignee: ADVANCED FLEXIBLE CIRCUITS CO., LTD., TAOYUAN COUNTY (TW)

(21) Appl. No.: 13/629,859

(22) Filed: Sep. 28, 2012

Related U.S. Application Data
(63) Continuation-in-part of application No. 12/848,390, filed on Aug. 2, 2010.

(30) Foreign Application Priority Data
Apr. 30, 2010 (TW) 099113975

(51) Int. Cl. H02G 3/02; H05K 9/00

(52) U.S. Cl. 174/350; 174/72 A

(57) ABSTRACT

A cable bundling structure is provided for being set in slidable engagement with a target cable. The cable bundling structure includes a helical wrap member, which wraps around a wrapped section of the target cable. The helical wrap member is selectively composed of one or more sections of wrapping turns and each section is made in a one-piece form having a predetermined wrap width, a predetermined helix angle, and a predetermined wrap diameter and extending a predetermined length in a wrapping direction. The helical wrap member helically wraps around the target cable in such a way that the helical wrap member is in slidable engagement with the target cable and serves as an external protection for the cable. The helical wrap member can be made of an insulation material or an electromagnetic shielding material, whereby besides structural protection of the cable for improving resistance against bending, the external protection formed by the helical wrap member also provides protection against electromagnetic interference (EMI).

### CROSS-REFERENCES TO RELATED APPLICATIONS

This application is a continuation-in-part of Ser. No. 12/848,390 filed on Aug. 2, 2010, entitled “CABLE BUNDLING STRUCTURE IN SLIDABLE ENGAGEMENT WITH CABLE”, currently pending.

### FIELD OF THE INVENTION

The present invention relates to a design of a cable bundling structure, and in particular to a cable bundling structure that is set in slidable engagement with a cable.

### BACKGROUND OF THE INVENTION

For all currently used electronic devices, since the amount of data transmitted through signal transmission cables is increased, the number of signal transmission cables is increased too and the frequency of the signals transmitted through the cables is getting high. Thus, differential mode becomes one of commonly used modes for high frequency transmission in order to reduce electromagnetic interference (EMI). This technique is commonly applied to for example USB or LVDS signals. However, it is often to bundle a large number of signal transmission cables together after these cables have been properly set up and this is, on one hand, for positioning of cables and, on the other hand, for protection purposes. The currently employ cable bundling techniques for bundling signal transmission cables mostly applies a length of adhesive tape, which is generally insulation, or a piece of conductive cloth to loop and bundle signal transmission cables in order to provide structural protection for improving resistance of the cables against bending or for serving as electromagnetic shielding against EMI for high-frequency transmission cables. However, such a conventional way of bundling cables often leads to excessive rigidity of the bundled cables, making it hard to bend or flex. Further, stress induced in the signal transmission cables may concentrate at a localized area, imposing undesired constraint to stretching of the signal transmission cables or even damaging the signal transmission cables. Consequently, signal transmission cables that are bundled in the conventional way is not fit for applications in slender or tiny hinge structures that are found in the fields of modern mobile phones, digital cameras, or notebook computers.

On the other hand, in the modem printed circuit board technology, a flexible printed circuit board is commonly used in various consumer electronic devices, such as digital cameras, mobile phones, and notebook computers, due to the fact that the flexible printed circuit board has the advantages of light weight, compactness, dynamic flexing, easy change of shape and also due to the flexible printed circuit board allowing for cable setup or laying according to the amount and shape of space available and providing a desired protection configuration.

However, the modem mobile phones, digital cameras, and notebook computers are often provided with a hinge structure that has been improved from a simply-structured single-axis hinge into a dual-axis or multi-axis structure and shows an increasingly miniaturized arrangement, making the bore of pivot much slenderer than ever. This prevents the conventional flat cables, as well as the protection structures thereof, from suiting the needs of such a change.

It is vital that that a flat cable or an external protection of a cable can endure frequent bending or the number of bending that they can take without damage is of vital importance. Under this condition, if a conventional flat cable or cable, as well as external protection thereof, is taken and even if the complete signal transmission assembly formed by the conventional flat cable is still capable of extending through a bore defined in a hinge device, when the electronic device is put into use, parts of the device is subjected to repeated moving or rotating and stress concentration may be found in a corner of the flat cable due to folding and/or rotating. Further, abrasion may occur between the cable and the hinge device. All these factors lead to a shortened service life due to being incapable of sustaining the design number of repeated bending. Since the conventional way of bundling cables is done by applying adhesive tape, conductive cloth, or PI like insulation material to ensure the cables in an organized form for assembling. However, the flat cable or the protection structure thereof may abrade each other due to displacement thereof caused by rotation of associated components, leading compression, distortion, and deformation of portions of the conductors of the cable or even breaking of the conductors that results in loss of capability of transmission. Further, the conventional way of bundling requires a large amount of human labor and is not easy for standardization.

### SUMMARY OF THE INVENTION

Thus, an objective of the present invention is to provide a cable bundling structure that is set in slidable engagement with a cable around which the structure warps in order to overcome the drawbacks found in the applications of signal transmission cables. Another objective of the present invention is to provide a pre-formed helical wrap member, which is made of one of insulation materials and electromagnetic-shielding materials.

The technical solution that the present invention adopts to solve the problems comprises a pre-formed helical wrap member, which is used to wrap around a wrapped section of a target cable. The helical wrap member is made in a one-piece form with a predetermined wrap width, a predetermined helix angle, and a predetermined wrap diameter and extends by a predetermined length in a wrapping direction. The helical wrap member, when helically wrapping around the target cable, forms slidable engagement with the target cable and serves as an external protection structure for the cable. The helical wrap member can be made of an insulation material or an electromagnetic shielding material, whereby besides structural protection of the cable for improving resistance against bending, the external protection formed by the helical wrap member also provides protection against electromagnetic interference (EMI).

A signal transmission cable that is wrapped by the cable bundling structure still has a sufficient clearance for movement, can be bent or flexed as desired, and substantially reduces stress concentration. A signal transmission flat cable according to the present invention can be applied to an electronic device having a single-axis or multiple-axis hinge structure, and since each individual signal transmission wire of the signal transmission flat cable is allowed to independently and freely flex and possesses certain clearance for movement, abrasion occurring between the signal transmission wires and the hinge structure, or stretching induced by stresses, or constraints imposed to the movement of the hinge structure can be improved. For a cable bundling structure made of an electromagnetic shielding material, protection against EMI caused by high frequency signals, such as transmission signals of differential mode that is commonly adopted in USB or LVDS systems, is also realized. Further, after being wrapped around a target cable, the helical wrap member according to the present invention allows for curved extension along a path that extends through various electronic components mounted on a substrate board to further enhance the value of application thereof.

The helical wrap member according to the present invention can be made of an insulation material, an electromagnetic shielding material, or a composite material thereof. When made of an electromagnetic shielding material, the helical wrap member also provides a function of eliminating electromagnetic interference to protect a cable wrapped thereby from interference by electromagnetic waves. Compared to the conventional cable protection structures, the present invention shows advantages in respect of easy assembling and reduction of cost, and allows for standardization of products.

### BRIEF DESCRIPTION OF THE DRAWINGS

The present invention will be apparent to those skilled in the art by reading the following description of preferred embodiments of the present invention, with reference to the attached drawings, in which:

FIG. 1 is a perspective view of a first embodiment according to the present invention;

FIG. 2 is a perspective view of a cable bundling structure shown in FIG. 1;

FIG. 3 is a side elevational view of the cable bundling structure;

FIG. 4 is a cross-sectional view taken along line 4-4 of FIG. 3;

FIG. 5 is a cross-sectional view showing a helical wrap member according to the present invention wraps around a target cable;

FIG. 6 is a cross-sectional view showing a helical wrap member according to the present invention wraps around a target cable;

FIG. 7 is a cross-sectional view showing a helical wrap member according to the present invention wraps around a target cable;

FIG. 8 is a schematic view showing an example where a helical wrap member according to the present invention wrapping around a target cable is applied to an electronic device;

FIG. 9 is a schematic view showing an example where a helical wrap member according to the present invention wrapping around a target cable is applied to an electronic device;

FIG. 10 is a schematic view showing an example where a helical wrap member according to the present invention wrapping around a target cable is applied to an electronic device;

FIG. 11 is a cross-sectional view showing a helical wrap member according to the present invention is wrapped around a target cable that is bundled in advance by a bundling layer;

FIG. 12 is a schematic view showing a helical wrap member according to the present invention is wrapped around a target cable of which a small portion is bundled in advance by a bundling layer;

FIG. 13 is a perspective view showing a second embodiment of the present invention, comprising a helical wrap member having a small wrap width;

FIG. 14 is a perspective view showing a third embodiment of the present invention, comprising a helical wrap member having a circular cross-section;

FIG. 15 is a perspective view showing a fourth embodiment of the present invention, comprising a helical wrap member that is composed of multiple sections of wrapping turns;

FIG. 16 is a perspective view showing a plurality of signal transmission cables is put together to form a bundled arrangement to serve as a target cable around which a helical wrap member according to the present invention wraps; and

FIG. 17 is a cross-sectional view showing a target cable to which the present invention is applicable comprising at least one pair of differential-mode high-frequency transmission lines;

FIG. 18 is a perspective view showing a fifth embodiment of the present invention;

FIG. 19 is a cross-sectional view showing a signal transmission bundle and a wire harness are wrapped by a helical wrap member in accordance with the fifth embodiment of the present invention;

FIG. 20 is a perspective view showing a clustered line wrapping member further wraps around the signal transmission bundle in accordance with the fifth embodiment of the present invention;

FIG. 21 is a cross-sectional view showing the signal transmission bundle is wrapped by a clustered line wrapping member, and the signal transmission bundle and the wire harness are wrapped by a helical wrap member in accordance with the fifth embodiment of the present invention;

FIG. 22 is a perspective view showing a clustered line wrapping member further wraps around the signal transmission bundle and a wire hardness wrapping member further wraps around the wire hardness in accordance with the fifth embodiment of the present invention;

FIG. 23 is a cross-sectional view showing the signal transmission bundle is wrapped by a clustered line wrapping member, the wire hardness is wrapped by a wire hardness wrapping member, and then the signal transmission bundle and the wire harness are wrapped by a helical wrap member in accordance with the fifth embodiment of the present invention; and

FIG. 24 is a perspective view showing a sixth embodiment of the present invention.

### DETAILED DESCRIPTION OF THE PREFERRED EMBODIMENTS

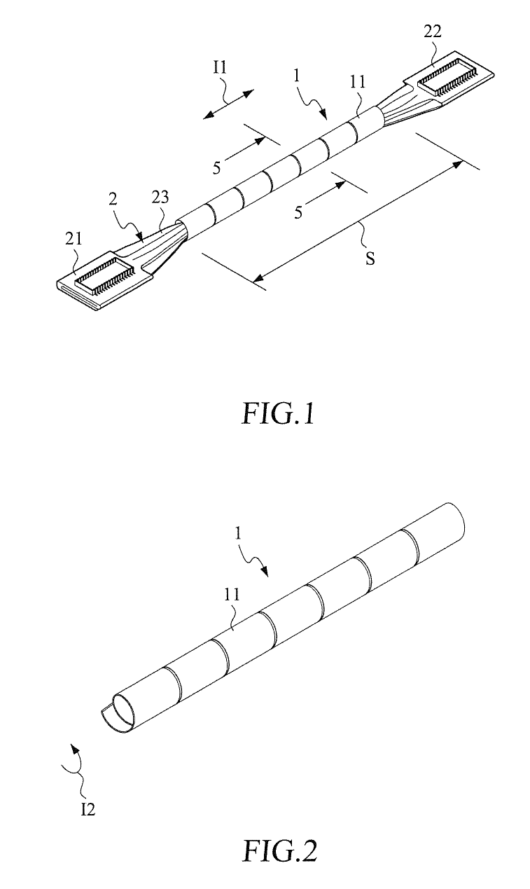

With reference to the drawings and in particular to FIG. 1, which shows a perspective view of a first embodiment of the present invention that provides a cable bundling structure for wrapping around a cable by being set in slidable engagement with the cable, the cable bundling structure according to the present invention is generally designated at 1 and is provided for wrapping around a predetermined wrapped section S of a target cable 2. The predetermined wrapped section S is located between a first connection section 21 and a second connection section 22 of the target cable 2. In the instant embodiment, the target cable 2 is composed of a plurality of conductor units 23 that extends in an extension direction I1 and is put together to form a bundled arrangement. The first connection section 21 and the second connection section 22 can be formed as a plug-like device or a socket-like device, or can be simply terminating ends.

The target cable 2 can be thin-film printed electronic flat cable, a flexible flat cable (FFC), a flexible printed circuit (FPC), an electronic cable, a Teflon cable, or a co-axial cable. In the example illustrated in the drawings, the target cable 2 comprises conductor units 23 each of which is formed of a piece of flexible printed circuit board having opposite first and second surfaces. A cluster section is arranged between the first connection section 21 and the second connection section 22 of the flexible printed circuit board and is composed of a plurality of clustered lines that is formed by slitting the flexible substrate board in an extension direction of the substrate board. Each clustered line is independently flexible.

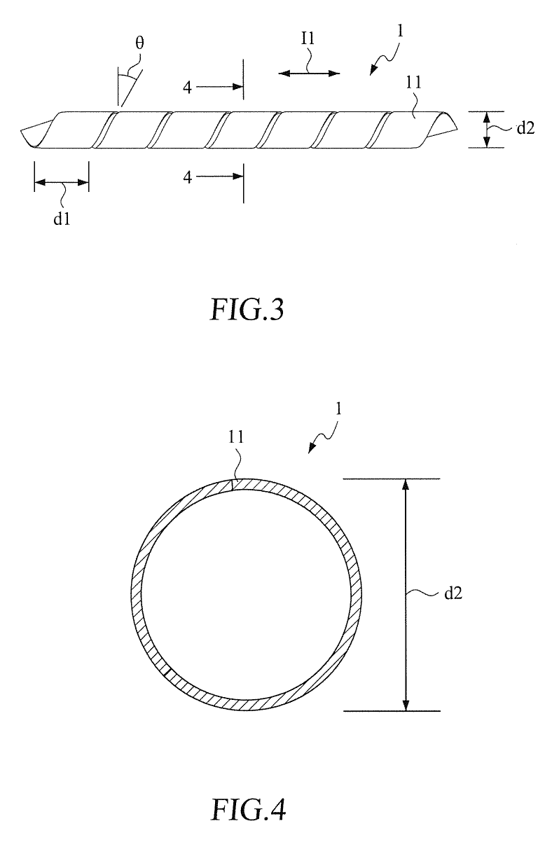

FIG. 2 shows a perspective view of the cable bundling structure 1 of FIG. 1. FIG. 3 shows a side elevational view of the cable bundling structure 1. FIG. 4 is a cross-sectional view taken along line 4-4 of FIG. 3. The cable bundling structure 1 according to the present invention comprises at least one helical wrap member 11, which is used to selectively wrap around a wrapped section S of a target cable 2 to bundle conductor units 23 of the wrapped section S together to form a bundled arrangement. The helical wrap member 11 is made in a one-piece form with a predetermined wrap width d1, a predetermined helix angle θ, and a predetermined wrap diameter d2 and extends a predetermined length in a wrapping direction 12. The helical wrap member 11 can be made of one of insulation material and electromagnetic shielding material.

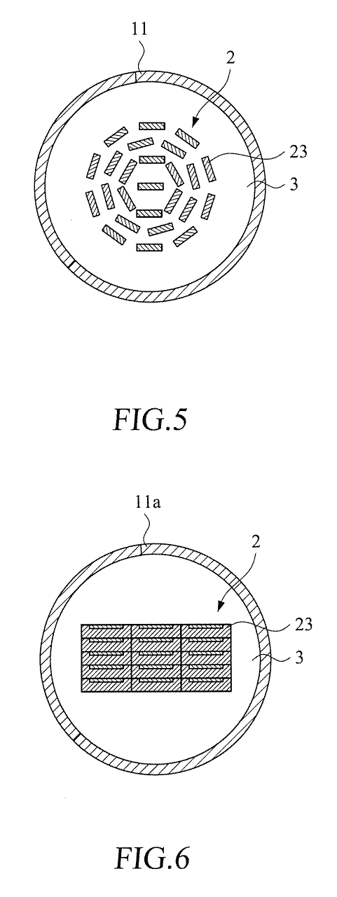

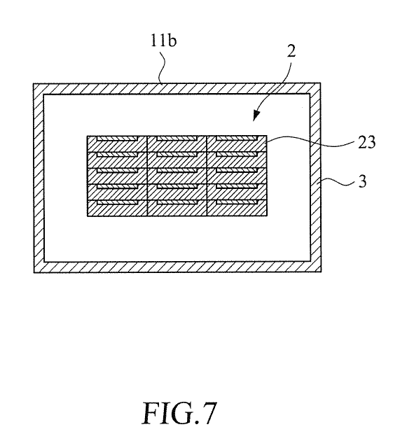

Referring to FIG. 5, when the helical wrap member 11 wraps around the target cable 2, a clearance space 3 is formed, at least partly, between an inside surface of the helical wrap member 11 and the target cable 2, so that the inside surface of the helical wrap member is in slidable engagement with an external surface of the target cable. The target cable 2, when bundled together to form the bundled arrangement, shows a cross-section of circle, square, or rectangle (see FIGS. 5 and 6). The helical wrap member 11, 11a, 11b can be of a circular, square, or rectangular cross-section (see FIGS. 5, 6, and 7).

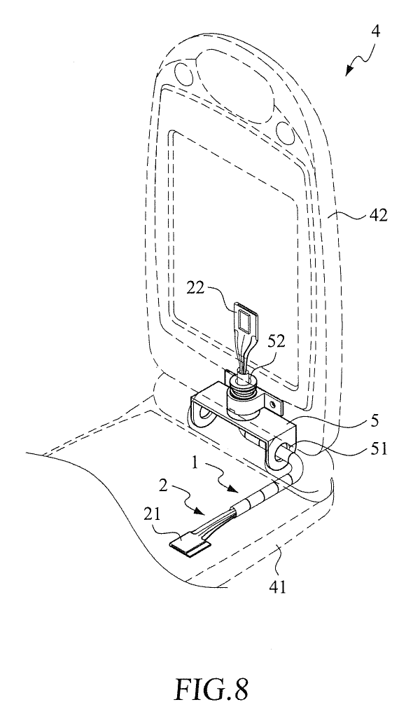

Referring to FIG. 8, the helical wrap member 11 of the present invention, after wrapped around a target cable 2, can be applied to an electronic device 4 (such as a notebook computer or a mobile phone), to serve for signal transmission between a main body 41 of the electronic device 4 and a rotatably mounted display screen 42. The drawing shows that the helical wrap member 11, after wrapping around the target cable 2, is set through holes 51, 52 defined through a hinge device 5 of the electronic device 4. When the display screen 42 undergoes frontward/rearward movement, lateral movement, rotation with respect to the main body 41, the cable 2 is protected and isolated by the helical wrap member 11 of the cable bundling structure 1 but is allowed to freely stretch within the helical wrap member 11 without being affected by any stress induced therein.

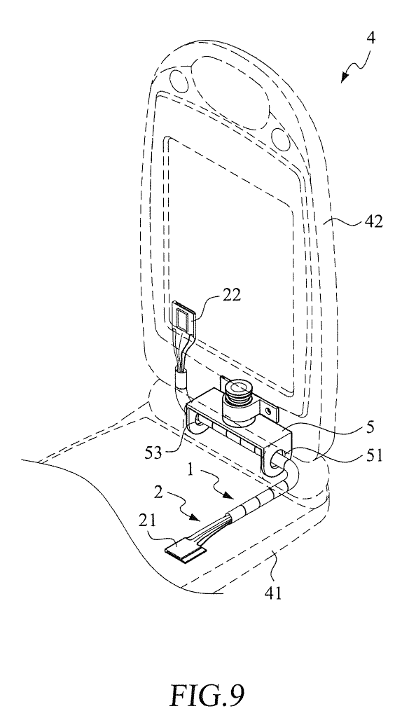

FIG. 9 is a schematic view showing the application of the helical wrap member 11, after wrapped around a target cable 2, to an electronic device 4 comprising a different construction of hinge device. The drawing shows that the helical wrap member 11, after wrapping around a target cable 2, is set through holes 51, 53 defined through a hinge device 5 of an electronic device 4. When the display screen 42 undergoes frontward/rearward deflection with respect to the main body 41, the cable 2 is similarly protected and isolated by the helical wrap member 11 of the cable bundling structure 1 but is allowed to freely stretch within the helical wrap member 11 without being affected by any stress induced therein.

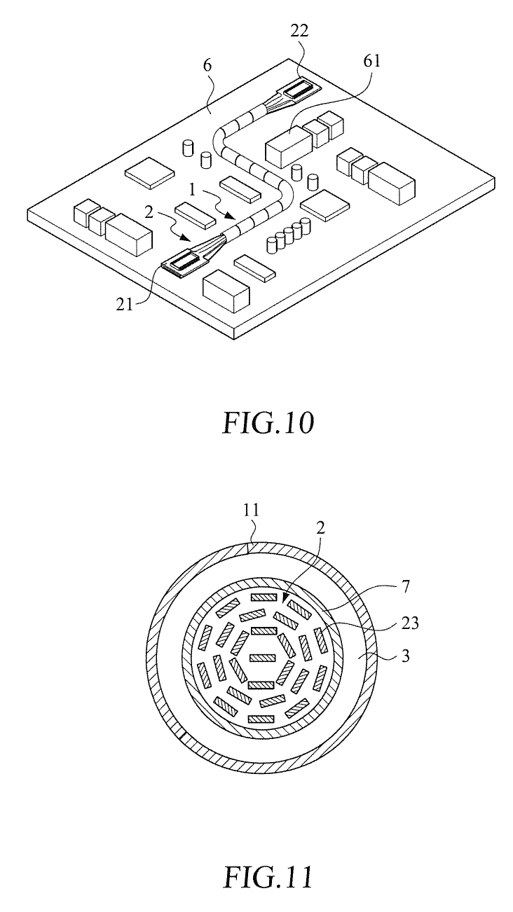

FIG. 10 is a schematic view showing curved bending of the helical wrap member 11, after wrapping around a target cable 2, for application to for example a circuit board. The drawing shows that the helical wrap member 11, after wrapping around a target cable 2, is set to extend along a path that extends through various electronic components 61 mounted to a substrate board 6, whereby the cable 2 is protected and isolated by the helical wrap member 11 of the cable bundling structure 1.

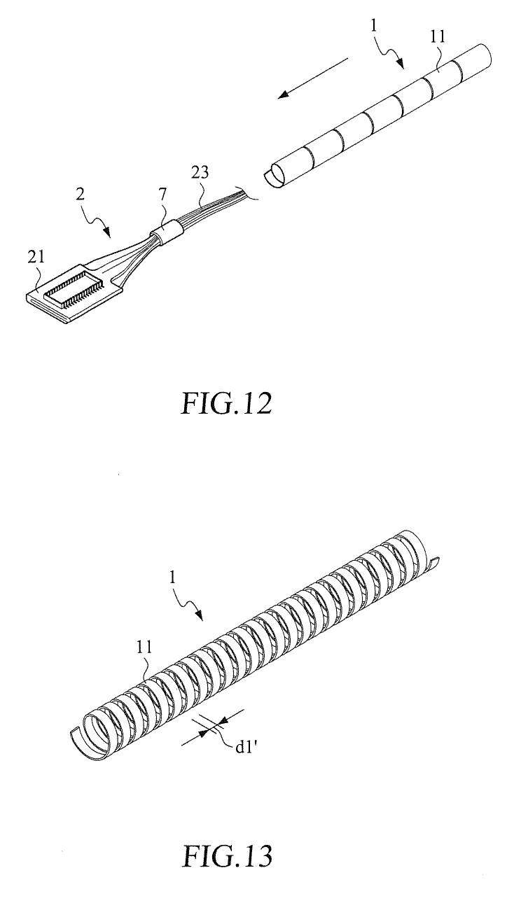

FIG. 11 shows that before a target cable 2 is wrapped by the helical wrap member 11, a bundling layer 7 is first applied to a surface of the target cable 2 for bundling the cable 2. The bundling layer 7 can be an insulation material or an electromagnetic shielding material. The bundling layer 7 is wrapped around the wrapped section S of the target cable 2, or is only wound around a small portion or fraction of the wrapped section S of the target cable 2 (see FIG. 12).

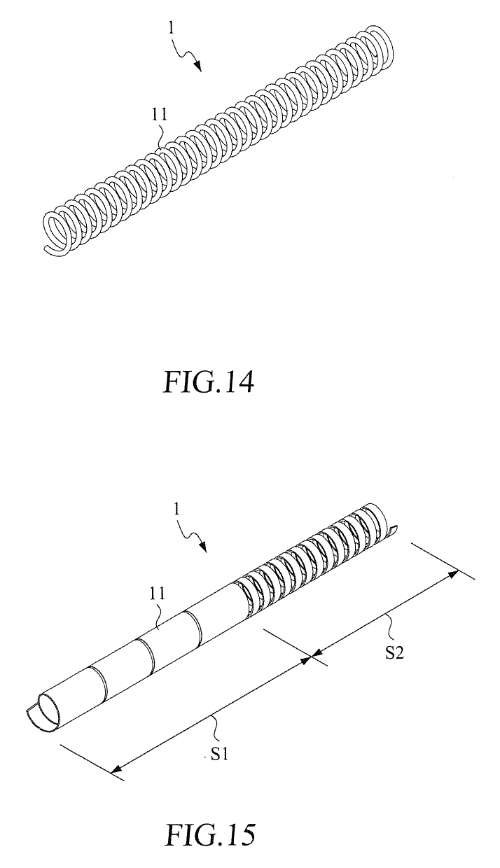

According to the present invention, the helical wrap member 11 can be modified in respect of wrap width d1, helix angle θ, wrap diameter d2, and cross-sectional shape to suit the needs of various applications and industries. For example, FIG. 13 shows an embodiment of the helical wrap member 11 that is of a small wrap width d1′, while FIG. 14 shows an embodiment of the helical wrap member 11 that is of a circular cross-section.

According to different requirements, the present invention provides a helical wrap member that is of a single section of wrapping turns (such as those shown in FIGS. 2, 13, and 14), or alternatively the helical wrap member is composed of multiple sections of wrapping turns, such as that shown in FIG. 15, which is composed of two sections S1, S2, each of which is made as a one-piece structure possessing individual wrap width, helix angle, and wrap diameter and extending a predetermined individual length in a wrapping direction.

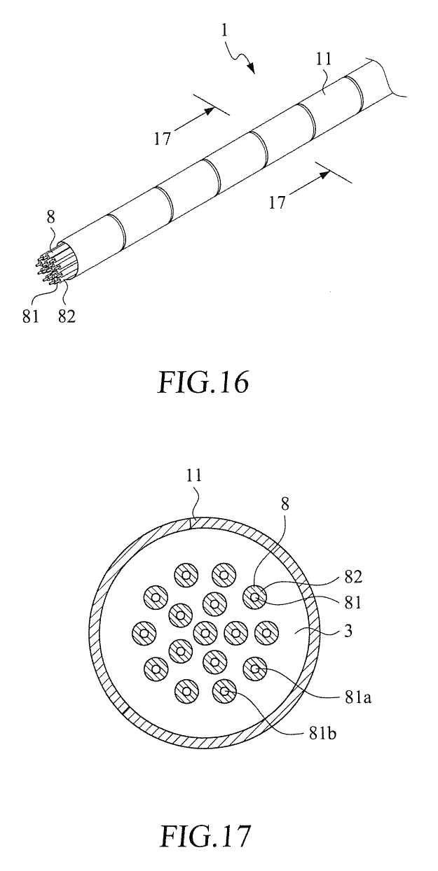

Further, although the target cables 2 described in the previous embodiments comprise a single flexible flat cable composed of a plurality of clustered lines or conductor units, the present invention is also applicable to a plurality of signal transmission cables 8 that is put together to form a bundled arrangement, as shown in FIG. 16, where each of the signal transmission cables 8 comprises a conductor 81 and an insulation layer 82 surrounding the conductor 81.

FIG. 17 shows a further embodiment where the target cable used in the present invention, besides being a cable for transmission of electrical signals, may selectively comprise at least one pair of differential-mode high-frequency transmission lines 81a, 81b.

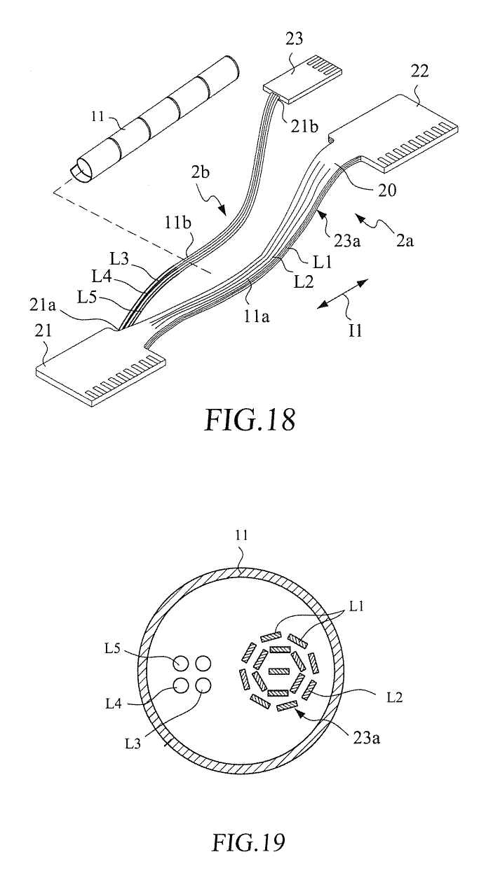

FIG. 18 is a perspective view showing a fifth embodiment of the present invention, and FIG. 19 is a cross-sectional view showing a signal transmission bundle and a wire harness are wrapped by a helical wrap member in accordance with the fifth embodiment of the present invention. In the instant embodiment, at least one signal transmission bundle 2a is connected between a first connection section 21 and a second connection section 22. The signal transmission bundle 2a comprises a flexible cable 20, which extends in an extension direction I1, and is composed of a plurality of clustered conduct units 23a that is formed by slitting the flexible cable 20 in the extension direction I1.

The clustered conduct units 23a in the signal transmission bundle 2a comprise at least a pair of differential-mode high-frequency signal transmission lines L1 used to transmit at least one differential-mode signal between the first connection section 21 and the second connection section 22.

Selectively, in the signal transmission bundle 2a, at least one common-mode signal transmission line L2 may be included therein for transmitting at least one common-mode signal between the first connection section 21 and the second connection section 22.

At least one wire harness 2b is provided with a first end 21a connected to the first connection section 21 and a second end 21b connected to a third connection section 23. The wire harness 2b comprises at least one wire which may be a power line L3, a ground line L4, or comprises a set of wires comprising the power line L3 and the ground line L4. Selectively, in the wire harness 2b, at least one common-mode signal transmission line L5 may be included therein for transmitting at least one common-mode signal between the first connection section 21 and the third connection section 23.

A helical wrap member 11 is used to wrap around the signal transmission bundle 2a and the wire harness 2b to form a bundled assembly. The helical wrap member 11 may be made of one of insulation material and electromagnetic shielding material. A clearance space is formed at least partly between an inside surface of the helical wrap member 11 and the signal transmission bundle 2a and the wire harness 2b, so that the inside surface of the helical wrap member 11 is in slidable engagement with an external surface of the signal transmission bundle 2a and the wire harness 2b.

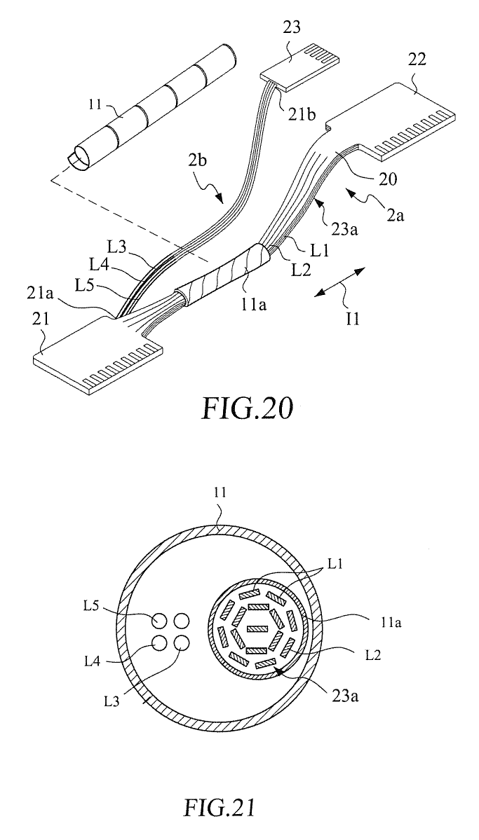

As shown in FIGS. 20 and 21, at least one clustered line wrapping member 11a is used to selectively wrap around the clustered conduct units 23a of the signal transmission bundle 2a to form a bundled arrangement. A helical wrap member 11 is then used to wrap around the signal transmission bundle 2a and the wire harness 2b to form a bundled assembly. The helical wrap member 11 may be made of one of insulation material and electromagnetic shielding material. The clustered line wrapping member 11a may be made of one of insulation material and electromagnetic shielding material.

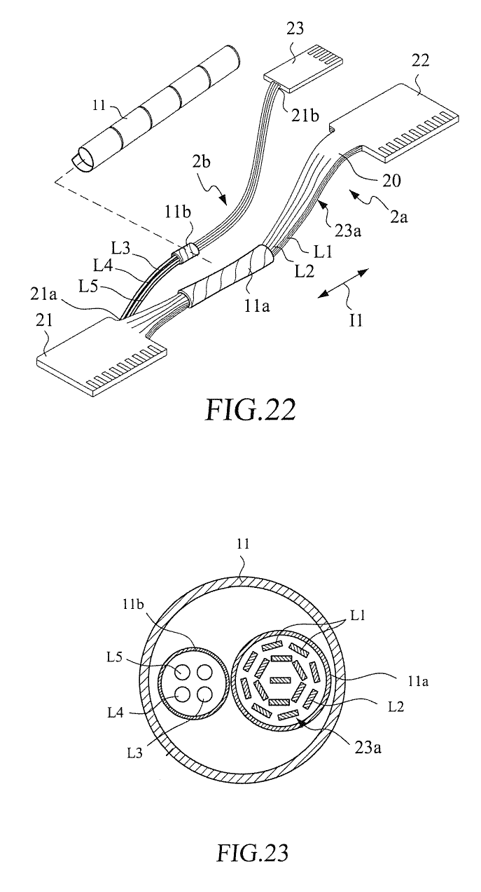

As shown in FIGS. 22 and 23, at least one clustered line wrapping member 11a is used to selectively wrap around the clustered conduct units 23a of the signal transmission bundle 2a. Further, at least one wire hardness wrapping member 11b is further used to selectively wrap around the wire harness 2b. Finally, a helical wrap member 11 is used to wrap around the signal transmission bundle 2a and the wire harness 2b to form a bundled assembly.

Each of the helical wrap member 11, the clustered line wrapping member 11a, and the wire hardness wrapping member 11b is preferably in a form of comprising at least one section of wrapping turn, which is made in a one-piece form having a predetermined wrap width, a predetermined helix angle, and a predetermined wrap diameter and extending a predetermined length in a wrapping direction.

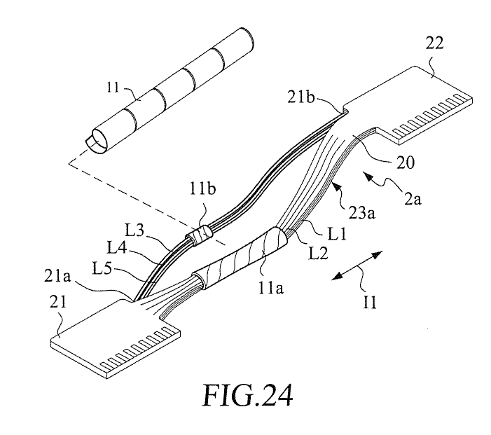

FIG. 24 is a perspective view showing a sixth embodiment of the present invention. In the instant embodiment, at least one signal transmission bundle 2a is connected between a first connection section 21 and a second connection section 22. The signal transmission bundle 2a comprises a flexible cable 20, which extends in an extension direction I1, and is composed of a plurality of clustered conduct units 23a that is formed by slitting the flexible cable 20 in the extension direction H. The clustered conduct units 23a may comprise at least a pair of differential-mode high-frequency signal transmission lines L1 and/or at least one common-mode signal transmission line L2.

At least one wire harness 2b is provided with a first end 21a connected to the first connection section 21 and a second end 21b connected to the second connection section 23. The wire harness 2b comprises at least one wire which may be a power line L3, a ground line L4, or comprises a set of wires comprising the power line L3 and the ground line L4. Selectively, in the wire harness 2b, at least one common-mode signal transmission line L5 may be included therein.

At least one clustered line wrapping member 11a may be used to selectively wrap around the clustered conduct units 23a of the signal transmission bundle 2a, and at least one wire hardness wrapping member 11b may be used to selectively wrap around the wire harness 2b. Finally, a helical wrap member 11 is used to wrap around the signal transmission bundle 2a and the wire harness 2b to form a bundled assembly.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A cable bundling structure, comprising:
at least one first connection section;
at least one second connection section;
at least one signal transmission bundle, comprising a flexible cable, which extends in an extension direction, which connects between the first connection section and the second connection section and is composed of at least a plurality of clustered conduct units that is formed by slitting the flexible cable in the extension direction;
at least one wire harness, which comprises at least one wire having a first end and a second end, the first end being connected to the first connection section; and
at least one helical wrap member, which wraps around the signal transmission bundle and the wire harness to bundle the clustered conduct units of the signal transmission bundle and the wire of the wire harness together.

2. The cable bundling structure as claimed in claim 1, wherein the flexible cable is selected from a group consisting of a thin-film printed electronic flat cable, a flexible flat cable (FFC), a flexible printed circuit (FPC), an electronic cable, a Teflon cable, and a co-axial cable.

3. The cable bundling structure as claimed in claim 1, wherein the wire harness comprises at least one power line.

4. The cable bundling structure as claimed in claim 1, wherein the wire harness comprises at least one ground line.

5. The cable bundling structure as claimed in claim 1, wherein the wire harness comprises at least one common-mode signal transmission line.

6. The cable bundling structure as claimed in claim 1, wherein the helical wrap member comprises at least one section of wrapping turns, which is made in a one-piece form having a predetermined wrap width, a predetermined helix angle, and a predetermined wrap diameter and extending a predetermined length in a wrapping direction.

7. The cable bundling structure as claimed in claim 1, wherein the helical wrap member helically wraps around the clustered conduct units of the signal transmission bundle and the wire of the wire harness, and a clearance space is formed at least partly between an inside surface of the helical wrap member and the signal transmission bundle and the wire harness, so that the inside surface of the helical wrap member is in slidable engagement with an external surface of the signal transmission bundle and the wire harness.

8. The cable bundling structure as claimed in claim 1, wherein the helical wrap member is made of one of an insulation material and an electromagnetic shielding material.

9. The cable bundling structure as claimed in claim 1, wherein the helical wrap member wrapping around the cable is set through holes defined in a hinge device.

10. The cable bundling structure as claimed in claim 9, wherein the cable has a first end adapted to connect to a first object set at one end of the hinge device and a second end adapted to connect to a second object set at an opposite end of the hinge device.

11. The cable bundling structure as claimed in claim 1, wherein the clustered conduct units comprise at least one pair of differential-mode high-frequency signal transmission lines.

12. The cable bundling structure as claimed in claim 1, wherein the clustered conduct units comprise at least one common-mode signal transmission line.

13. The cable bundling structure as claimed in claim 1, further comprising at least one wire hardness wrapping member, which wraps around the wire harness, and then the helical wrap member wraps around the signal transmission bundle and the wire harness.

14. The cable bundling structure as claimed in claim 13, wherein the wire hardness wrapping member is made of one of an insulation material and an electromagnetic shielding material.

15. The cable bundling structure as claimed in claim 13, wherein the wire hardness wrapping member comprises at least one section of wrapping turn, which is made in a one-piece form having a predetermined wrap width, a predetermined helix angle, and a predetermined wrap diameter and extending a predetermined length in a wrapping direction.

16. The cable bundling structure as claimed in claim 1, further comprising at least one clustered line wrapping member, which wraps around the clustered conduct units, and then the helical wrap member wraps around the signal transmission bundle and the wire harness.

17. The cable bundling structure as claimed in claim 16, wherein the clustered line wrapping member is made of one of an insulation material and an electromagnetic shielding material.

18. The cable bundling structure as claimed in claim 16, wherein the clustered line wrapping member comprises at least one section of wrapping turn, which is made in a one-piece form having a predetermined wrap width, a predetermined helix angle, and a predetermined wrap diameter and extending a predetermined length in a wrapping direction.

19. The cable bundling structure as claimed in claim 1, wherein the second end of the wire harness is connected to the second connection section.

20. The cable bundling structure as claimed in claim 1, further comprising a third connection section, and the second end of the wire harness being connected to the third connection section.
